(19) United States
(12) Patent Application Publication
(10) Pub. No.: US 2014/0264422 A1
(43) Pub. Date: Sep. 18, 2014

(54) Optoelectronic Semiconductor Component and Conversion Element

(71) Applicant: OSRAM OPTO SEMICONDUCTORS GMBH, Regensburg (DE)

(72) Inventors: Reiner Windisch, Pettendorf (DE); Hailing Cui, Regensburg (DE); Gertrud Kraeuter, Regensburg (DE); Markus Schneider, Nittendorf - Schoenhofen (DE)

(73) Assignee: OSRAM OPTO SEMICONDUCTORS GMBH, Regensburg (DE)

(21) Appl. No.: 14/354,098

(22) PCT Filed: Oct. 9, 2012
(86) PCT No.: PCT/EP2012/069951

§ 371 Date: Apr. 24, 2014

(30) Foreign Application Priority Data
Oct. 24, 2011 (DE) 10 2011 116 752.1

(51) Int. Cl. H01L 33/50; C09K 11/02; H01L 33/58

(52) U.S. Cl. CPC H01L 33/504; H01L 33/58; C09K 11/025
USPC 257/98; 252/301.4 F

(57) ABSTRACT

In at least one embodiment, an optoelectronic semiconductor component includes an optoelectronic semiconductor chip. The semiconductor component includes a conversion element that is arranged to convert at least some radiation emitted by the semiconductor chip into radiation of a different wavelength. The conversion element comprises at least one luminescent substance and scattering particles and also at least one matrix material. The scattering particles are embedded in the matrix material. A difference in the refractive index between the matrix material and a material of the scattering particles at a temperature of 300 K is at the most 0.15. The difference in the refractive index between the matrix material and the material of the scattering particles at a temperature of 380 K is greater than at a temperature of 300 K.

This patent application is a national phase filing under section 371 of PCT/EP2012/069951, filed Oct. 9, 2012, which claims the priority of German patent application 10 2011 116 752.1, filed Oct. 24, 2011, each of which is incorporated herein by reference in its entirety.

### TECHNICAL FIELD

An optoelectronic semiconductor component is provided. A conversion element for an optoelectronic semiconductor component is also provided.

### SUMMARY OF THE INVENTION

Embodiments provide an optoelectronic semiconductor component and a conversion element therefor, by means of which a comparatively constant color emission can be achieved with respect to changes in temperature.

In at least one embodiment, the optoelectronic semiconductor component comprises at least one optoelectronic semiconductor chip. The optoelectronic semiconductor chip is provided to generate electromagnetic radiation. In particular, the optoelectronic semiconductor chip comprises a semiconductor layer sequence.

The semiconductor layer sequence is preferably based on a III-V compound semiconductor material. The semiconductor material is, for example, a nitride compound semiconductor material such as AlₙIn₁₋ₙ₋ₘGaₘN or a phosphide compound semiconductor material, such as, AlₙIn₁₋ₙ₋ₘGaₘP or even an arsenide compound semiconductor material such as AlₙIn₁₋ₙ₋ₘGaₘAs, wherein in each case 0≦n≦1, 0≦m≦1 and n+m≦1. The semiconductor layer sequence can comprise dopants and additional substances. However, for the sake of simplicity only the essential substances of the crystal lattice of the semiconductor layer sequence, i.e., Al, As, Ga, In, N or P, are stated, even if these can be partially replaced or supplemented by small amounts of other materials. The semiconductor layer sequence is preferably based on AlInGaN.

The semiconductor layer sequence includes at least one active layer which is arranged to generate electromagnetic radiation. The active layer includes in particular at least one pn transition and/or at least one quantum well structure. Radiation generated by the active layer during operation lies in particular in the spectral range between 400 nm and 800 nm inclusive.

In accordance with at least one embodiment of the semiconductor component, this includes a conversion element. The conversion element is arranged to convert at least some radiation emitted by the semiconductor chip during operation into radiation of a different wavelength. For example, the semiconductor chip emits blue light and the conversion element converts some of this blue light into green and/or green-yellow and/or green-orange and/or red light. In a particularly preferred manner, the semiconductor component emits mixed radiation, composed of the radiation emitted by the conversion element and the radiation generated directly by the semiconductor chip. The mixed radiation is, for example, white light.

In accordance with at least one embodiment of the semiconductor component, the conversion element contains one or more luminescent substances. The luminescent substances are based, for example, on a rare earth-doped garnet such as YAG:Ce, a rare earth-doped orthosilicate such as (Ba, Sr)₂SiO₄:Eu or a rare earth-doped silicon oxynitride or silicon nitride such as (Ba, Sr)₂Si₅N₈:Eu. Several different luminescent substances can be present in the conversion element, mixed together or spatially separated from one another.

In accordance with at least one embodiment of the semiconductor component, the conversion element includes scattering particles. Owing to a difference in the refractive index with respect to the surroundings and/or owing to reflective properties and/or owing to light diffraction, the scattering particles are arranged to scatter the radiation converted by the conversion element and/or the radiation generated directly by the semiconductor chip. The scattering particles preferably absorb none or substantially none of the radiation generated by the semiconductor chip or the radiation converted by the conversion element. Furthermore, a material of the scattering particles can be permeable for the radiation generated by the semiconductor chip or the radiation converted by the conversion element.

In accordance with at least one embodiment, the conversion element comprises at least one matrix material. The matrix material is, for example, a silicone, a silicone-epoxy hybrid material or an epoxy. The matrix material is preferably clear and transparent for the radiation generated by the semiconductor chip and the radiation converted by the conversion element. The scattering particles are at least partly embedded in the matrix material. This means that all or some of the scattering particles are in places arranged in direct contact with the matrix material. In particular, the scattering particles are mixed into the matrix material in a homogeneously distributed manner.

In accordance with at least one embodiment of the semiconductor component, a refractive difference between the matrix material and the material of the scattering particles at a temperature of 300 K is at the most 0.15. It is possible that the difference in the refractive index is at the most 0.10 or at the most 0.07 or at the most 0.05 or at the most 0.03. That is to say, the refractive indices of the matrix material and of the material of the scattering particles do not differ from each other, or only differ from each other slightly, at room temperature.

In accordance with at least one embodiment of the semiconductor component, the difference in the refractive index between the matrix material and the material of the scattering particles at a temperature of 380 K and/or at a temperature of 400 K and/or at a temperature of 420 K is greater than at 300 K. That is to say, the difference in the refractive index increases, starting from room temperature to a stationary operating temperature of the semiconductor chip. By way of an increase in the difference in the refractive index, the scattering particles have a greater scattering effect at elevated temperature than at room temperature.

In at least one embodiment of the optoelectronic semiconductor component, this comprises one or more optoelectronic semiconductor chips in order to generate electromagnetic radiation. The semiconductor component includes a conversion element which is arranged to convert at least some radiation emitted by the semiconductor chip into radiation of a different wavelength. The conversion element comprises at least one luminescent substance and scattering particles as well as at least one matrix material. The scattering particles are partly or completely embedded in the matrix material. A difference in the refractive index between the matrix material and a material of the scattering particles at a temperature of 300 K is at the most 0.15. The difference in the refractive index between the matrix material and the material of the scattering particles at a temperature of 380 K is greater than at a temperature of 300 K.

Added to the conversion element in a targeted manner is thus a material in the form of the scattering particles, whose refractive index at room temperature is close to the refractive index of the matrix material. Furthermore, the scattering particles are of a size such that a light-scattering effect is produced. When the temperature is increased, the refractive index of the matrix material—which is in particular a silicone—is reduced. If the refractive indices of the matrix material and of the material of the scattering particles are close to each other at room temperature, then this lowering of the refractive index of the matrix material results in a large change in the scattering effect of the scattering particles when the temperature is increased.

An increased scattering effect changes an average travel path of radiation, generated directly by the semiconductor chip, in the conversion element. A degree of conversion is also increased hereby, that is to say more radiation generated by the semiconductor chip is converted into other radiation by the conversion element. As a result, a blue proportion of the radiation is reduced and the chromaticity coordinate of the mixed radiation is moved in the direction away from blue. A change in the chromaticity coordinate, caused by a change in wavelength of the radiation emitted directly by the optoelectronic semiconductor chip upon a change in temperature, can hereby be at least partially compensated for.

In accordance with at least one embodiment of the semiconductor component, the scattering particles have an average diameter of at least 50 nm or of at least 250 nm or of at least 400 nm. Alternatively or in addition, the average diameter of the scattering particles is at the most 20 μm or at the most 10 μm or at the most 5.5 μm or at the most 3 μm. That is to say, the scattering particles have a comparatively large diameter. In particular, the scattering particles are, in relation to an average diameter, clearly larger than in the case of thixotropic agents. The scattering particles can have a specific distribution of the average diameter.

In accordance with at least one embodiment of the semiconductor component, the material of the scattering particles is a silicon dioxide, a glass, quartz, a silicon nitride or a metal fluoride such as barium fluoride, calcium fluoride or magnesium fluoride. It is possible for the scattering particles to be formed from several of said materials or for scattering particles made of different materials to be used in combination.

In accordance with at least one embodiment of the semiconductor component, the matrix material is a silicone or a silicone-epoxy hybrid material, wherein the refractive index of the matrix material at room temperature is at least 1.38 or at least 1.40 and alternatively or in addition at the most 1.54 or at the most 1.50 or at the most 1.48. In this case, room temperature refers to a temperature of 300 K. For example, the refractive index of the matrix material is 1.41 or 1.46 with a tolerance of at the most 0.01.

In accordance with at least one embodiment of the semiconductor component, the refractive index of the matrix material at room temperature is smaller than or equal to the refractive index of the scattering particles. In particular, the refractive index of the matrix material is reduced as the temperature increases and the refractive index of the material of the scattering particles increases as the temperature increases, at least in a temperature range of 300 K to 400 K. It is also possible for the refractive index of the material of the scattering particles to likewise decrease as the temperature increases, but to a lesser degree than the refractive index of the matrix material.

A change in the refractive index of the scattering particles is approximately 0.1×10⁻⁵ K⁻¹ to 1×10⁻⁵ K⁻¹ and is thus substantially negligible compared with the change in the refractive index of the matrix material which is a silicone. The change in the refractive index of silicone is, in the relevant temperature range, approximately −4×10⁻⁴ K⁻¹.

In accordance with at least one embodiment of the semiconductor component, a weight proportion of the scattering particles, based on the matrix material or the entire conversion element is at least 0.5% or at least 1%. Alternatively or in addition, the weight proportion is at the most 50% or at the most 20% or at the most 12% or at the most 5%.

In accordance with at least one embodiment of the semiconductor component, the luminescent substance is present in the form of particles. An average diameter of the luminescent particles is then, for example, at least 2 μm or at least 3 μm or at least 5 μm. Alternatively or in addition, the average diameter is at the most 20 μm or at the most 15 μm or at the most 40 μm.

In accordance with at least one embodiment of a semiconductor component, the luminescent particles are embedded in the matrix material together with the scattering particles. The conversion element then preferably comprises precisely one matrix material. It is possible for the luminescent particles and the scattering particles to be mixed, in particular homogeneously mixed.

It is likewise possible for the luminescent particles to be present in a partially sedimented manner and for the scattering particles to be present in the matrix material in a homogeneously or substantially homogeneously distributed manner. The luminescent particles can also be at an increased concentration on a side of the conversion element facing the semiconductor chip and the scattering particles on a side of the conversion element facing away from the semiconductor chip.

In accordance with at least one embodiment of the semiconductor component, a weight proportion of the luminescent substance, based on the matrix material or based on the entire conversion element, is between 5% and 80% inclusive. Preferably, the weight proportion is between 10% and 25% inclusive or between 5% and 20% inclusive or between 60% and 80% inclusive.

In accordance with at least one embodiment of the semiconductor component, the luminescent particles have a larger average diameter than that of the scattering particles. For example, the average diameters differ from one another by at least a factor of 2 or by at least a factor of 5. Further, it is possible for the number of scattering particles to exceed the number of luminescent particles, e.g., by at least a factor of 2 or by at least a factor of 5 or by at least a factor of 10.

In accordance with at least one embodiment of the semiconductor component, the luminescent substance and the scattering particles are present without being mixed. For example, the luminescent substance or the luminescent particles are present in a first matrix material and the scattering particles are present in a second matrix material. It is likewise possible for the luminescent substance to be formed into a compact layer and the matrix material having the scattering particles to be applied onto this layer. A distance between the scattering particles and the luminescent substance is, for example, at the most 250 μm or at the most 150 μm or at the most 50 μm. Preferably, the luminescent substance and the matrix material with the scattering particles particularly homogeneously distributed therein are arranged directly adjacent one another.

In accordance with at least one embodiment of the semiconductor component, the luminescent substance of the conversion element is formed by a single luminescent substance. Preferably, the luminescent substance is then formed from precisely one of the following materials: a green-emitting orthosilicate having the elemental formula (Baₓ, Sr_{y}, Ca_{1-x-y})_{2-z} Eu_{z}SiO₄ with 0.25≦x<1, 0≦y≦0.75, 0<z≦0.5 and 0<a<1; a green-emitting nitride-orthosilicate having the elemental formula (Baₓ, Sr_{y}, Ca_{1-x-y})_{2-z}Eu_{z}Si(Oa, N_{(0.67-0.67a)})₄ with 0.25≦x<1, 0≦y≦0.75, 0<z≦0.5 and 0<a<1.

If reference is made to a nitride-orthosilicate then it is in each case possible that this alternatively or in addition has the elemental formula AE_{(2-1,5x-y)}REₓEu_{y}SiO_{(4-1,5x)}Nₓ with 0<x 0.1 and 0<y 0.2 and with AE=Mg, Ca, Sr and/or Ba and RE=Sr, Y and/or one or more elements from the group of lanthanides.

In accordance with at least one embodiment of the semiconductor component, the conversion element comprises a first luminescent substance and a second luminescent substance. The first luminescent substance is provided to emit in the green and/or green-yellow spectral range. The second luminescent material is preferably arranged to emit at a longer wavelength than the first luminescent substance, preferably in the red spectral range or in the red-orange spectral range. The two mutually different luminescent substances can be homogeneously mixed or can follow each other in a layer-like manner.

The first luminescent substance and the second luminescent substance are preferably present in one of the following material combinations:

green-emitting orthosilicate having the formula (Baₓ, Sr_{y}, Ca_{1-x-y})_{2-z}Eu_{z}SiO₄ with 0.25≦x≦1, 0≦y≦0.75 and 0≦z≦0.5 and red-emitting nitride having the formula (Cax, Sr₁₋ₓ)_{2-y}Eu_{y}AlSi(N_{z},O_{(1.5-1.5z)})₃ with 0≦x≦1, 0<y≦0.4 and 0<z≦1,

green-emitting orthosilicate having the formula (Baₓ, Sr_{y}, Ca_{1-x-y})_{2-z}Eu_{z}SiO₄ with 0.25≦x≦1, 0≦y≦0.75 and 0≦z≦0.5 and red-emitting nitride having the formula (Srₓ, Ba₁₋ₓ)_{2-y}Eu_{y}Si₅N₈ with 0<x<1 and 0<y<0.3,

green-emitting nitride-orthosilicate having the formula (Baₓ, Sr_{y}, Ca_{1-x-y})_{2-z}Eu_{z}Si(Oa, N_{(0.67-0.67a)})₄ with 0.25≦x≦1, 0≦y≦0.75, 0<z≦0.5 and 0<a<1 and red-emitting nitride having the formula (Caₓ, Sr₁₋ₓ)_{2-y}Eu_{y}AlSi(N_{z}, O_{(1.5-1.5z)})₃ with 0≦x≦1, 0<y≦0.4 and 0<z≦1, or

green-emitting nitride-orthosilicate having the formula (Baₓ, Sr_{y}, Ca_{1-x-y})_{2-z}Eu_{z}Si(Oa, N_{(0.67-0.67a)})₄ with 0.25≦x≦1, 0≦y≦0.75, 0<z≦0.5 and 0<a<1 and red-emitting nitride having the formula (Srₓ, Ba₁₋ₓ)_{2-y}Eu_{y}Si₅N₈ with 0<x<1, 0<y≦0.3.

In accordance with at least one embodiment of the semiconductor component, the difference in the refractive index between the matrix material and the material of the scattering particles at 300 K is at the most 0.06 or at the most 0.05 and the difference in refractive index at 400 K is at least 0.075 or at least 0.065. Alternatively or in addition, the difference in the refractive index changes from 300 K to 400 K by at least 20% or by at least 30%.

A scattering mechanism is also provided. The scattering mechanism can be used in a conversion element, as provided in one or more embodiments of the semiconductor chip described above. Features of the scattering means are thus also disclosed for the optoelectronic semiconductor chip and vice-versa.

In at least one embodiment, the scattering mechanism is used with a conversion element, wherein the conversion element is configured to convert radiation emitted by a semiconductor chip into radiation of a different wavelength. The conversion element includes a matrix material and scattering particles that are embedded in the matrix material. A difference in the refractive index between the matrix material and a material of the scattering particles is smaller at a temperature of 300 K than at a temperature of 380 K.

### BRIEF DESCRIPTION OF THE DRAWINGS

An optoelectronic semiconductor component described herein and a conversion element described herein will be explained in more detail hereinafter using exemplified embodiments and with reference to the drawing. Like elements are provided with like reference numerals in the individual figures. However, the elements are not illustrated to scale but rather individual elements can be illustrated excessively large for better understanding.

In the drawing:

FIGS. 1 to 6 show schematic illustrations of exemplified embodiments of scattering bodies described herein and optoelectronic semiconductor chips described herein;

FIGS. 7A to 7B show a schematic illustration of chromaticity coordinate shifts when the temperature changes; and

FIG. 8 shows a schematic illustration of chromaticity coordinate changes for different scattering particles.

### DETAILED DESCRIPTION OF ILLUSTRATIVE EMBODIMENTS

FIG. 1 shows a sectional illustration of an exemplified embodiment of an optoelectronic semiconductor component 1. The semiconductor component 1 includes an optoelectronic semiconductor chip 2 which is mounted in a housing 4 in a recess. The semiconductor chip 2 is preferably a light-emitting diode, LED for short, which emits blue light.

Further, the semiconductor component 1 includes a conversion element 3 which is disposed downstream of the semiconductor chip 2 in a radiation direction and is located, as is the semiconductor chip 2, in the recess of the housing 4. The conversion element 3 is arranged to absorb some of the radiation generated by the semiconductor chip 2 during operation and convert it into radiation which is different therefrom and has a longer wavelength. The conversion element 3 is simultaneously used as scattering means. Optionally, the conversion element 3 is formed in a lens-like manner.

The conversion element 3 comprises a luminescent substance or several luminescent substances as well as scattering particles. The luminescent substance(s) and the scattering particles can be present homogeneously distributed in the conversion element 3. At room temperature, the scattering particles and a matrix material, in which the luminescent substance and the scattering particles are embedded, have an approximately identical refractive index. If the temperature of the semiconductor chip 2 and thus of the conversion element 3 increases when the semiconductor component 1 is switched on, then a difference in the refractive index between the matrix material of the conversion element 3 and the scattering particles in the conversion element 3 increases.

It is possible for the scattering particles to have an average diameter between 2.5 μm and 8.5 μm inclusive and to be formed from silicon dioxide. At 300 K, the matrix material has, for example, a refractive index between 1.36 and 1.48 inclusive. A weight proportion of the scattering particles in the conversion element 3 is, for example, between 0.5% and 15% inclusive or between 6% and 15% inclusive.

When the temperature increases, e.g., from about 300 K to about 380 K, a dominant wavelength emitted directly by the semiconductor chip 2 shifts, for example by about 3 nm to 5 nm towards higher wavelengths. The dominant wavelength is in particular the wavelength which is produced as the intersection of the spectral color line of the CIE chromaticity diagram with a straight line, wherein this straight line, starting from the white point in the CIE chromaticity diagram, extends through the actual chromaticity coordinate of the radiation.

Since a maximum sensitivity of the blue color receptor in the human eye is at approximately 450 nm, the chromaticity coordinate of the radiation emitted by the semiconductor chip 2 shifts into blue, at least if a wavelength of maximum intensity of this radiation is less than 450 nm at room temperature, as is preferably the case in this instance. Mixed radiation radiated from the semiconductor component 1, composed of the radiation generated directly from the semiconductor chip 2 and the radiation converted by the conversion element 3, can hereby appear blue. Alternatively or in addition, a shift in the chromaticity coordinate into blue can also occur by virtue of the fact that a conversion efficiency of the luminescent substances decreases as the temperature increases. The shift in the chromaticity coordinate owing to this effect can also be at least reduced by the combination of the two luminescent substances.

By increasing the difference in the refractive index between the matrix material and the scattering particles at higher temperatures, a travel path of the blue light generated in the semiconductor chip 2 in the conversion element 3 is increased, whereby a conversion efficiency of the conversion element 3 increases. In other words, more blue light is converted into, for example, green light and/or red light and thus less blue light is emitted from the semiconductor component 1. A shift in the chromaticity coordinate after switching on the semiconductor component 1, caused by a change in the dominant wavelength of the radiation generated by the semiconductor chip 2 when the temperature increases, can hereby be avoided or clearly reduced in a heating-up phase of the semiconductor chip 2.

FIG. 2 illustrates a further exemplified embodiment of the semiconductor component 1. The semiconductor chip 2 is mounted on a carrier 5. The carrier 5 is, for example, a conductor board or a printed circuit board. As in the case of the other figures and also in the case of the housing 4 of FIG. 1, electrical conductive tracks and/or bond wires are not illustrated for the sake of simplicity.

On a light-exiting side of the semiconductor chip 2, which faces away from the carrier 5, a luminescent substance plate 36 is mounted. The luminescent substance(s) is/are located in the luminescent substance plate 36. The luminescent substance plate 36 is, for example, a ceramic plate in which luminescent particles are embedded or sintered. The matrix material 34 with the scattering particles 33 embedded therein is located in a direction away from the carrier 5 and in the lateral direction around the semiconductor chip and around the luminescent substance plate 36. The luminescent substance plate 36 is thus located between the semiconductor chip 2 and the matrix material 34 with the scattering particles 33. The matrix material 34 with the scattering particles 33 is formed in a hood-like manner and forms, together with the luminescent substance plate 36, the conversion element 3.

The scattering particles 33 have, for example, an average diameter between 400 nm and 1.5 μm inclusive and are produced from silicon dioxide. The refractive index of the matrix material at 300 K is in particular between 1.39 and 1.48 inclusive. A weight proportion of the scattering particles 33, based on the matrix material 34, is, for example, between 0.75% and 6% inclusive or between 5% and 60% inclusive.

In the exemplified embodiment of FIG. 3, the luminescent substance plate 36 and the matrix material 34 with the scattering particles 33 are formed in a hood-like manner. The luminescent substance plate 36 can comprise a further matrix material in which the luminescent particles are embedded.

In the exemplified embodiment of FIG. 4, a layer consisting of a connecting agent 7 is located in each case between the semiconductor chip 2 and the luminescent substance plate 36 and between the luminescent substance plate 36 and the matrix material 34 with the scattering particles 33. The individual elements are attached to one another by way of the connecting agent 7 which is formed, for example, by a silicone. A thickness D of the layers of the connecting agent 7 is, for example, at the most 20 μm or at the most 10 μm in each case. The matrix material 34 with the scattering particles 33 optionally does not protrude beyond the semiconductor chip 2 in a lateral direction.

The conversion element 3 can be surrounded by a casting compound 6. Such a casting compound 6 may also be present in all the other exemplified embodiments. The casting compound 6 is, for example, transparent, made for instance from a silicone or contains admixtures for light-scattering or light-filtering.

In the case of the exemplified embodiment of FIG. 5, the semiconductor component 1 comprises a semiconductor chip 2a emitting in the blue spectral range and a semiconductor chip 2b emitting the red spectral range, wherein the semiconductor chips 2a, 2b are both mounted on the carrier 5. The conversion element 3 is disposed downstream of the semiconductor chip 2a emitting in the blue spectral range. The semiconductor chip 2b emitting in the red spectral range can be free of a scattering means.

In accordance with FIG. 6, the conversion element 3 is disposed downstream of both the semiconductor chips 2a, 2b, which can also be a semiconductor chip emitting in the blue spectral range and a semiconductor chip emitting in the red spectral range.

The changes in chromaticity coordinates Δcx and Δcy are plotted with respect to the temperature T in degrees Celsius in FIG. 7 for various compositions of the conversion element; FIG. 7A relates to the red chromaticity coordinate cx and FIG. 7B relates to the green chromaticity coordinate cy, with regard to the CIE chromaticity diagram.

The curves labeled with “a” in FIGS. 7A and 7B relate to a conversion agent which does not comprise scattering particles. The curves b, c, d each relate to conversion elements 3 as described above. All the curves a-d have a weight proportion of 10% of a luminescent substance which is an orthosilicate emitting in the green spectral range. A weight proportion of the scattering particles, which are formed of silicon dioxide is 0% in curve a, about 5% in curve b, approximately 10% in curve c and about 12.5% in curve d.

FIG. 7 shows that the chromaticity coordinates cx, cy are clearly shifted in curve a and that a shift can be reduced at higher temperatures by adding scattering particles; see curves b, c, d.

The shift in the chromaticity coordinate Δcx, Δcy relates in each case to the mixed radiation radiated from the semiconductor component 1 and formed of the radiation emitted directly from the semiconductor chip 2 and the radiation converted by the conversion element 3.

In FIG. 8, efficiency E is plotted with respect to a chromaticity coordinate shift Δcx+Δcy for various scattering particles. FIG. 8 merely shows the spectral shift of a semiconductor component 1 emitting white light solely on the basis of the change in the refractive index of the matrix material. The refractive index of the matrix material is reduced by approximately 0.035, corresponding to a temperature change of from 25° C. to 120° C. A change in the efficiency E owing to temperature changes in the semiconductor chip is not considered in FIG. 8. FIG. 8 thus relates only to the change in the efficiency E owing to the influence of the change in the refractive index between the matrix material and the scattering particles at the stated temperature change from 25° C. to 120° C.

Curve a relates to scattering particles having a refractive index of approximately 1.8 of a conventional diffuser. In the case of an increase in a diffuser concentration in the matrix material—refractive index approximately 1.5—there is only a reduction in the efficiency E but there is no significant shift in the chromaticity coordinate.

Curve b relates to silicon dioxide spheres having an average diameter of 1 μm as scattering particles. The silicon dioxide spheres have a refractive index of 1.46 at room temperature and the associated matrix material, which is a silicone, has a refractive index of 1.41, likewise at room temperature. The individual points of the curve b relate to a weight proportion of the scattering particles of 0%, 1%, 2%, 5% and 10%. The efficiency E is reduced as the weight proportion of the scattering particles increases, but a shift in the chromaticity coordinate increases. A preferred shift in the chromaticity coordinate of approximately 0.02 is achieved with a weight proportion of just approximately 1%.

The same scattering particles as in curve b are used in curve c but the matrix material, which is a silicone, has a higher refractive index of 1.46 at room temperature. It can be seen that the change in chromaticity coordinate approximately corresponds to that of curve b, but the efficiency E decreases to a lesser extent.

In the case of curve e, silicon dioxide spheres having a refractive index of 1.46 at 300 K are added at a weight proportion of 2% to a silicone as the matrix material having a refractive index of 1.41 at room temperature. Curve e reflects different average diameters of the scattering particles. A particularly favorable ratio of efficiency E and shift in the chromaticity coordinate is produced in particular with the scattering particles having an average size of 500 nm.

Curve d relates to the same scattering particles as curve b, but a matrix material, which is a silicone, is used having a refractive index of 1.51 with a tolerance of at the most 0.005 or at the most 0.01 or at the most 0.03, at room temperature. The refractive index of the matrix material is thus higher at room temperature than the refractive index of the scattering particles. Therefore, a difference in the refractive index between the matrix material and the scattering particles decreases as the temperature increases and the chromaticity coordinate shifts into blue as the temperature changes. All the features in relation to the conversion element, the carrier, the housing, the casting material and/or the semiconductor chip, as described in conjunction with the above-mentioned exemplified embodiments, can also be drawn on, in principle, for the embodiment of curve d.

The invention described herein is not limited by the description with reference to the exemplified embodiments. Rather, the invention includes any new feature and any combination of features included in particular in any combination of features in the claims, even if this feature or this combination itself is not explicitly stated in the claims or exemplified embodiments.

1-15. (canceled)

16. An optoelectronic semiconductor component comprising:
an optoelectronic semiconductor chip configured to generate electromagnetic radiation; and
a conversion element arranged to convert at least a part of radiation emitted by the semiconductor chip into radiation of a different wavelength;
wherein the conversion element comprises a luminescent substance and scattering particles;
wherein the conversion element comprises a matrix material in which the scattering particles are embedded;
wherein a difference in refractive index between the matrix material and a material of the scattering particles at a temperature of 300 K is at most 0.06 and at a temperature of 400 K it is at least 0.075;
wherein the difference in the refractive index at a temperature of 380 K is greater than the difference in the refractive index at 300 K;
wherein the luminescent substance is present in the form of particles and is embedded in the matrix material together with the scattering particles;
wherein the luminescent substance and the scattering particles are mixed;
wherein the scattering particles have an average diameter of at least 400 nm and at most 10 μm;
wherein a weight proportion of the scattering particles in the conversion element is between 0.5% and 50% inclusive;
wherein a weight proportion of the luminescent substance is between 5% and 20% inclusive; and
wherein the particles of the luminescent substance have an average diameter between 5 μm and 40 μm inclusive, which is larger than the average diameter of the scattering particles.

17. The optoelectronic semiconductor component according to claim 16, wherein the scattering particles have an average diameter between 250 nm and 20 μm inclusive.

18. The optoelectronic semiconductor component according to claim 16, wherein the material of the scattering particles comprises at least one material selected from the group consisting of silicon dioxide, a glass, quartz, silicon nitride, a metal fluoride.

19. The optoelectronic semiconductor component according to claim 18, wherein the matrix material is a silicone or a silicone-epoxy hybrid material and has a refractive index between 1.38 and 1.54 inclusive.

20. The optoelectronic semiconductor component according to claim 16, wherein a distance between the scattering particles and the luminescent substance is at most 250 μm.

21. The optoelectronic semiconductor component according to claim 16, wherein the luminescent substance is the only luminescent substance and consists of a green-emitting orthosilicate having the elemental formula (Baₓ, Sr_{y}, Ca_{1-x-y})_{2-z}Eu_{z}SiO₄ with 0.25≦x<1, 0≦y≦0.75, 0<z≦0.5 and 0<a<1.

22. The optoelectronic semiconductor component according to claim 16, wherein the luminescent substance is the only luminescent substance and consists of a green-emitting nitride-orthosilicate having the elemental formula (Baₓ, Sr_{y}, Ca_{1-x-y})_{2-z}Eu_{z}Si(Oₐ, N_{(0.67-0.67a)})₄ with 0.25≦x<1, 0≦y≦0.75, 0<z≦0.5 and 0<a<1.

23. The optoelectronic semiconductor component according to claim 16, wherein the conversion element comprises a first luminescent substance and a second luminescent substance, wherein the first luminescent substance is provided to emit green and the second luminescent substance is provided to emit red or red-orange.

24. The optoelectronic semiconductor component according to claim 16, wherein
the scattering particles have an average diameter between 2.5 μm and 8.5 μm inclusive;
the material of the scattering particles is silicon dioxide;
the matrix material has a refractive index between 1.36 and 1.48 inclusive;
the semiconductor chip is configured to generate blue light;
the weight proportion of the scattering particles is between 6% and 15% inclusive; and
the conversion element comprises the luminescent substance and a second luminescent substance which are mixed together with the scattering particles in the matrix material.

25. The optoelectronic semiconductor component according to claim 16, wherein:
the scattering particles have an average diameter between 400 nm and 1.5 μm inclusive;
the material of the scattering particles is silicon dioxide;
the matrix material has a refractive index between 1.39 and 1.48 inclusive;
the semiconductor chip is configured to generate blue light; and
the weight proportion of the scattering particles is between 0.75% and 6% inclusive.

26. A conversion element, which is configured to convert radiation emitted by a semiconductor chip into radiation of a different wavelength, the conversion element comprising:
a matrix material; and
scattering particles embedded in the matrix material;
wherein a difference in refractive index between the matrix material and a material of the scattering particles is smaller at a temperature of 300 K than at a temperature of 380 K.

27. The conversion element according to claim 26, wherein a weight proportion of the scattering particles in the conversion element is between 0.5% and 50% inclusive.

28. The conversion element according to claim 26, further comprising a luminescent substance, wherein the luminescent substance is present in the form of particles and is embedded in the matrix material together with the scattering particles and wherein the luminescent substance and the scattering particles are mixed.

29. The conversion element according to claim 28, wherein a weight proportion of the luminescent substance is between 5% and 20% inclusive and the particles of the luminescent substance have an average diameter between 5 μm and 40 μm inclusive, which is larger than the average diameter of the scattering particles.

30. The conversion element according to claim 26, further comprising a luminescent substance, wherein a distance between the scattering particles and the luminescent substance is at most 250 μm.

31. The conversion element according to claim 26, wherein the difference in the refractive index at 300 K is at most 0.06 and at 400 K it is at least 0.075.

32. An optoelectronic semiconductor component comprising:
an optoelectronic semiconductor chip configured to generate electromagnetic radiation; and
a conversion element arranged to convert at least some of the radiation emitted by the semiconductor chip into radiation of a different wavelength;
wherein the conversion element comprises at least one luminescent substance and scattering particles;
wherein the conversion element comprises a matrix material in which the scattering particles are embedded;
wherein a difference in the refractive index between the matrix material and a material of the scattering particles at a temperature of 300 K is at the most 0.15;
wherein the difference in the refractive index at a temperature of 380 K is smaller than at 300 K;
wherein the matrix material has a larger refractive index at a temperature of 300 K than a material of the scattering particles; and
wherein a chromaticity coordinate of mixed radiation emitted by the semiconductor component is shifted into blue at a temperature of 380 K, relative to a temperature of 300 K.
